(19) United States
(12) Patent Application Publication
(10) Pub. No.: US 2025/0056941 A1
(43) Pub. Date: Feb. 13, 2025

(54) OPTOELECTRONIC ELEMENT AND METHOD FOR PRODUCING AN OPTOELECTRONIC ELEMENT

(71) Applicant: ams-OSRAM International GmbH, Regensburg (DE)

(72) Inventors: Erwin LANG, Regensburg (DE); Simon SCHWALENBERG, Brennberg (DE); Igor STANKE, Regensburg (DE); Patrick HÖRNER, Bamberg (DE); Marc PHILIPPENS, Regensburg (DE)

(21) Appl. No.: 18/717,553

(22) PCT Filed: Nov. 24, 2022
(86) PCT No.: PCT/EP2022/083089

§ 371 Date: Jun. 7, 2024

(30) Foreign Application Priority Data
Dec. 9, 2021 (DE) 10 2021 132 495.5

(51) Int. Cl. H01L 33/60; H01L 33/54; H01L 33/56

(52) U.S. Cl. CPC H01L 33/60; H01L 33/54; H01L 33/56; H01L 2933/005; H01L 2933/0058

(57) ABSTRACT

An optoelectronic element includes a carrier, a semiconductor chip with an active layer for generating electromagnetic radiation, and an encapsulation element. The semiconductor chip is arranged on a main surface of the carrier. The encapsulation element is arranged on the main surface of the carrier, such that the optoelectronic element includes an intermediate space between the main surface of the carrier and the encapsulation element. The semiconductor chip is arranged in the intermediate space. The intermediate space is at least partially filled with hollow beads.

An optoelectronic element and a method for producing an optoelectronic element are specified.

At least one object of certain embodiments is to provide an optoelectronic element having an improved emission characteristic and a method for producing an optoelectronic element having an improved emission characteristic.

According to at least one embodiment, the optoelectronic element comprises a carrier. The carrier comprises, for example, a glass or a polymer. The carrier is preferably configured for mechanically stabilizing the optoelectronic element. In particular, the carrier comprises conductive tracks and/or contact points for electrically contacting the optoelectronic element. The conductive tracks and/or contact points can comprise a metal, for example.

According to at least one further embodiment, the optoelectronic element comprises a semiconductor chip with an active layer for generating electromagnetic radiation. The semiconductor chip is preferably arranged on a main surface of the carrier. The main surface of the carrier can correspond to a main extension plane of the carrier, or can run parallel thereto at least in places.

The semiconductor chip is a light-emitting diode, for example. In particular, the semiconductor chip comprises a semiconductor layer sequence, which preferably comprises a III-V compound semiconductor material. A III/V compound semiconductor material comprises at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. A nitride compound semiconductor preferably comprises AlₙGaₘIn₁₋ₙ₋ₘN, where 0≤n≤1, 0≤m≤1 and n+m≤1. A phosphide compound semiconductor preferably comprises AlₙGaₘIn₁₋ₙ₋ₘP, where 0≤n≤1, 0≤m≤1 and n+m≤1. Such binary, ternary or quaternary compounds may also comprise one or more dopants and additional components, for example.

In particular, the semiconductor chip is configured for emitting electromagnetic radiation in a spectral range between ultraviolet light and infrared light. For example, the semiconductor chip generates electromagnetic radiation in the visible spectral range during operation. The semiconductor chip is preferably a flip chip. A flip chip comprises electrical terminal contacts on a single side, for example on a side of the semiconductor chip facing the carrier. The electrical terminal contacts are preferably configured as a reflective layer that reflects electromagnetic radiation generated during operation. This can increase an outcoupling efficiency of the electromagnetic radiation generated by the semiconductor chip during operation.

The carrier comprises, for example, a printed circuit board. In particular, the printed circuit board comprises electrical connection points that are configured for electrically contacting the semiconductor chip.

The optoelectronic element is surface mountable, for example. In particular, the optoelectronic element comprises terminal contacts on a surface of the carrier opposite the main surface, which are configured for an external electrical contacting and/or for mounting the optoelectronic element onto an external surface.

In particular, the side of the carrier opposite to the main surface is free of semiconductor chips for generating electromagnetic radiation. In other words, semiconductor chips for generating electromagnetic radiation are arranged exclusively on the main surface of the carrier and thus only on one side of the carrier.

According to at least one further embodiment, the optoelectronic element comprises an encapsulation element. The encapsulation element is preferably arranged on the main surface of the carrier, such that the optoelectronic element comprises an intermediate space between the main surface of the carrier and the encapsulation element. The encapsulation element comprises a polymer, for example, and is formed in particular as a layer on or over the main surface of the carrier. For example, the encapsulation element is laminated and/or bonded to the main surface of the carrier by means of a hot-melt adhesive.

For example, the encapsulation element is arranged exclusively on the main surface of the carrier. In other words, a side of the carrier opposite the main surface is free of the encapsulation element.

In particular, the encapsulation element is transparent to electromagnetic radiation generated by the semiconductor chip during operation. Preferably, a large part of the electromagnetic radiation generated during operation, for example more than 50%, is coupled out from the optoelectronic element via the encapsulation element.

According to at least one further embodiment of the optoelectronic element, the semiconductor chip is arranged in the intermediate space. The intermediate space can extend over a sub-region of the main surface of the carrier, or over the entire main surface of the carrier, for example. The intermediate space can be closed or comprise at least one opening.

According to at least one further embodiment of the optoelectronic element, the intermediate space is at least partially filled with hollow beads. The hollow beads preferably comprise a glass or a polymer, or are made of a glass or a polymer. In particular, the hollow beads are configured for mechanically stabilizing the intermediate space. For example, the hollow beads are filled with air or a protective gas, in particular nitrogen. Preferably, the intermediate space, which is at least partially filled with hollow beads, has optical properties that come as close as possible to the optical properties of an air-filled intermediate space. In particular, an average refractive index of the intermediate space filled with hollow beads for electromagnetic radiation generated during operation is smaller than a refractive index of the encapsulation element.

In particular, the average refractive index corresponds to an average value of a refractive index of the hollow beads filled with air or an inert gas, as well as a refractive index of a matrix material that can be located in the intermediate space between the hollow beads, wherein the average value is weighted with corresponding volume proportions of the hollow beads and the matrix material in the intermediate space.

According to a preferred embodiment, the optoelectronic element comprises the following features:
a carrier,
a semiconductor chip with an active layer for generating electromagnetic radiation,
an encapsulation element, wherein
the semiconductor chip is arranged on a main surface of the carrier,
the encapsulation element is arranged on the main surface of the carrier, such that the optoelectronic element comprises an intermediate space between the main surface of the carrier and the encapsulation element,
the semiconductor chip is arranged in the intermediate space, and
the intermediate space is at least partially filled with hollow beads.

The optoelectronic element described herein is based on the idea to reduce the total reflection of electromagnetic radiation generated during operation at a radiation outcoupling surface of the encapsulation element. This improves the emission characteristics of the optoelectronic element. In particular, the radiation outcoupling surface of the encapsulation element is an interface between the encapsulation element and the environment outside of the optoelectronic element. For example, the radiation outcoupling surface of the encapsulation element is a main surface of the encapsulation element facing away from the carrier.

The part of electromagnetic radiation generated during operation that is totally reflected at the radiation outcoupling surface of the encapsulation element can be reduced, for example, by a plane-parallel air gap between the semiconductor chip and the encapsulation element. In particular, the plane-parallel air gap is arranged plane-parallel to the main surface of the carrier and/or plane-parallel to the radiation outcoupling surface of the semiconductor chip.

In particular, the plane-parallel air gap is filled with ambient air or a protective gas, for example nitrogen. Electromagnetic radiation coupled out from the semiconductor chip is refracted at the crossover to the encapsulation element by the plane-parallel air gap. In particular, this reduces an angle of incidence of electromagnetic radiation generated during operation at the radiation outcoupling surface of the encapsulation element. As a result, a smaller portion of the electromagnetic radiation generated during operation is incident on the radiation outcoupling surface of the encapsulation element at large angles of incidence. The totally reflected portion of electromagnetic radiation generated during operation is thus reduced.

Totally reflected electromagnetic radiation is, for example, waveguided within the encapsulation element and can thus be coupled out at undesirable locations, for example at defects, metallic conductor tracks or at the edge of the optoelectronic element. As a result, the contrast of the optoelectronic element declines due to the total reflection, for example.

However, producing a plane-parallel air gap can be technically complex and therefore costly. For example, the encapsulation element is a protective film, whereby the semiconductor chip on the carrier is laminated into the protective film by means of a thermally deformable hot-melt adhesive. In particular, the hot-melt adhesive can enclose the semiconductor chip on all surfaces that are not covered by the carrier. This makes it difficult to form a plane-parallel air gap between the radiation outcoupling surface of the semiconductor chip and the encapsulation element.

In the optoelectronic element described herein, the plane-parallel air gap is replaced, in particular, by a layer of hollow beads. Preferably, the hollow beads are very stable against a compressive load. Accordingly, the encapsulation element can be applied to the hollow beads, creating a stable intermediate space that is at least partially filled with hollow beads and whose optical properties are similar, in particular, to a plane-parallel air gap.

In order to reduce unwanted scattered light, the optoelectronic element can additionally comprise an absorption film with a low absorption. By reducing the portion of totally reflected electromagnetic radiation at the radiation outcoupling surface of the encapsulation element, the absorption film can advantageously comprise a lower absorption, whereby a transparency of the optoelectronic element is advantageously increased.

According to at least one further embodiment of the optoelectronic element, the carrier and/or the encapsulation element comprises a flexible film. The carrier and/or the encapsulation element can also be formed as a flexible film. In particular, the flexible film comprises a polymer, for example polyamide, polyethylene naphthalate (PEN), polyethylene terephthalate (PET), or polyvinyl butyral (PVB).

According to at least one further embodiment of the optoelectronic element, the carrier and the encapsulation element are transparent to electromagnetic radiation generated by the semiconductor chip during operation. In particular, a majority, for example more than 90%, of the electromagnetic radiation generated by the semiconductor chip during operation is transmitted through the encapsulation element and/or the carrier. The optoelectronic element is, for example, a so-called light-in-glass module. Accordingly, for example, luminescent pictograms, symbols, numbers or letters can be displayed by small light-emitting diodes within a transparent glass pane.

According to at least one further embodiment of the optoelectronic element, the carrier comprises metallic conductor tracks for electrically contacting the semiconductor chip. The metallic conductor tracks are preferably thin enough to maintain the flexibility of the carrier.

According to at least one further embodiment of the optoelectronic element, the semiconductor chip has an edge length of at most 500 micrometers. Preferably, the semiconductor chip has an edge length of at most 200 micrometers, particularly preferably of at most 60 micrometers. In particular, the semiconductor chip is so small that the transparency of the optoelectronic element in the visible spectral range is only slightly influenced by the semiconductor chip embedded therein.

According to a further embodiment of the optoelectronic element, the hollow beads are made of glass. For example, the hollow beads comprise borosilicate glass or consist of borosilicate glass.

According to at least one further embodiment of the optoelectronic element, the hollow beads have an average diameter between 1 micrometer and 100 micrometers, inclusive. Preferably, the hollow beads have an average diameter between 1 micrometer and 10 micrometers, inclusive.

According to at least one further embodiment of the optoelectronic element, the hollow beads have an average wall thickness between 0.1 micrometers and 5 micrometers, inclusive. The wall thickness corresponds to a radial extension of a spherical shell of the hollow bead. Preferably, the average wall thickness of a hollow bead is at least by a factor of 10 smaller than the diameter of the hollow bead.

According to at least one further embodiment of the optoelectronic element, the hollow beads are transparent to electromagnetic radiation generated by the semiconductor chip during operation. The intermediate space, which is at least partially filled with hollow beads, preferably has optical properties that are similar to a plane-parallel air gap between the semiconductor chip and the encapsulation element.

In particular, the average refractive index of the intermediate space filled with hollow beads for electromagnetic radiation generated by the semiconductor chip during operation is smaller than the refractive index of the encapsulation element.

According to at least one further embodiment of the optoelectronic element, the hollow beads form a dense sphere packing, wherein the dense sphere packing completely fills the intermediate space. A packing density of the hollow beads is, for example, at least 50%. In other words, at least 50% of the volume of the intermediate space is occupied by the hollow beads, for example. For example, the dense sphere packing has a statistical distribution of the hollow beads, or is formed as a hexagonal dense sphere packing or a Cartesian sphere packing, for example, whereby intermediate forms are also possible.

According to at least one further embodiment of the optoelectronic element, the intermediate space extends over the entire main surface of the carrier. Thus, the encapsulation element is not in direct contact with the main surface of the carrier. For example, the dense sphere packing of hollow beads forms a continuous layer arranged between the main surface of the carrier and the encapsulation element, wherein the semiconductor chip is embedded in the layer of hollow beads.

According to a further embodiment of the optoelectronic element, the intermediate space is a closed cavity. In particular, the semiconductor chip is arranged in the closed cavity, wherein the closed cavity is preferably filled with a dense sphere packing of hollow beads. The hollow beads preferably cover all surfaces of the semiconductor chip that are not covered by the carrier.

According to at least one further embodiment of the optoelectronic element, a lateral extension of the closed cavity corresponds to at most five times an edge length of the semiconductor chip. Here and in the following, lateral refers to a direction parallel to the main surface of the carrier. In particular, the closed cavity has an extension such that electromagnetic radiation generated by the semiconductor chip during operation, which is emitted at an angle of 45° to a surface normal of the main surface of the carrier, impinges on an interface between the encapsulation element and the intermediate space, which is arranged parallel to the main surface of the carrier.

According to at least one further embodiment of the optoelectronic element, the hollow beads are at least partially embedded in a matrix material, wherein the matrix material connects the hollow beads in a mechanically stable manner. The matrix material is, for example, a polymer, in particular an epoxy resin, an acrylate or a polyamide. The matrix material preferably has a lower refractive index for electromagnetic radiation generated during operation than the encapsulation element.

According to at least one further embodiment of the optoelectronic element, the matrix material does not completely fill spaces between the hollow beads. In particular, the matrix material is configured for punctually bonding the hollow beads at contact surfaces between adjacent hollow beads. Free spaces between the hollow beads are thus preferably not filled with the matrix material, but with ambient air or a protective gas, for example nitrogen.

According to at least one further embodiment of the optoelectronic element, the hollow beads are arranged laterally spaced from the semiconductor chip and comprise a reflective surface. For example, the hollow beads form a frame that completely encloses the semiconductor chip laterally and projects above the semiconductor chip in a direction perpendicular to the main surface of the carrier. In particular, the hollow beads are arranged such that a plane-parallel air gap is arranged between the semiconductor chip and the encapsulation element after the encapsulation element has been applied. The plane-parallel air gap is mechanically stabilized, for example, by the hollow beads spaced laterally from the semiconductor chip. In particular, the hollow beads are embedded in a matrix material, with the matrix material forming a reflective surface with the hollow beads embedded therein. Alternatively and/or additionally, the hollow beads may comprise a reflective surface coating.

According to at least one further embodiment of the optoelectronic element, a plurality of semiconductor chips is arranged on the main surface of the carrier, wherein the plurality of semiconductor chips forms a pictogram. The optoelectronic element is, for example, a light-in-glass module, wherein the carrier and the encapsulation element are, in particular, transparent to electromagnetic radiation generated by the semiconductor chip during operation.

Further, a method for producing an optoelectronic element is specified herein. All features of the optoelectronic element are also disclosed for the method for producing the optoelectronic element, and vice versa.

According to an embodiment of the method for producing an optoelectronic element, a carrier is first provided. The carrier is, for example, a flexible film which comprises a polymer and is transparent to electromagnetic radiation in the visible spectral range.

According to at least one further embodiment of the method, a semiconductor chip is applied onto a main surface of the carrier, wherein the semiconductor chip comprises an active layer for generating electromagnetic radiation. The semiconductor chip is preferably a micro-LED or a mini-LED with an edge length of less than 100 micrometers. The carrier comprises, for example, metallic conductor tracks for electrically contacting the semiconductor chip.

According to at least one further embodiment of the method, an encapsulation element is applied to the main surface of the carrier, wherein an intermediate space is formed between the encapsulation element and the main surface of the carrier. The encapsulation element is preferably a flexible film that is transparent to electromagnetic radiation generated by the semiconductor chip during operation and is mechanically bonded to the main surface of the carrier using a hot-melt adhesive, for example. The semiconductor chip is arranged in the intermediate space.

According to at least one further embodiment of the method for producing an optoelectronic element, the intermediate space is at least partially filled with hollow beads. The hollow beads preferably comprise a glass or are made of a glass.

According to a preferred embodiment, the method for producing an optoelectronic element comprises the following steps:
providing a carrier,
applying a semiconductor chip onto a main surface of the carrier, the semiconductor chip comprising an active layer for generating electromagnetic radiation,
applying an encapsulation element onto the main surface of the carrier, wherein
an intermediate space is formed between the encapsulation element and the main surface of the carrier,
the semiconductor chip is arranged in the intermediate space, and
the intermediate space is at least partially filled with hollow beads.

According to at least one further embodiment of the method, the hollow beads are at least partially embedded in a matrix material and are applied onto the main surface of the carrier by a screen printing process before the encapsulation element is applied. In particular, the hollow beads form a dense sphere packing, with the matrix material bonding the hollow beads together at contact surfaces, while free spaces between the hollow beads preferably remain free of the matrix material.

For example, the matrix material and the hollow beads embedded therein are applied to a sub-region of the main surface of the carrier around the semiconductor chip, as well as to all surfaces of the semiconductor chip that are not covered by the carrier. Alternatively, the matrix material and the hollow beads embedded therein are applied to the entire main surface of the carrier, wherein the matrix material with the hollow beads embedded therein cover the semiconductor chip on all surfaces that are not covered by the carrier. In this case, the matrix material with the hollow beads embedded therein forms a continuous layer which is arranged between the carrier and the encapsulation element.

Furthermore, the hollow beads and the matrix material can be applied to the main surface of the carrier in such a way that a cavity is formed around the semiconductor chip. In particular, the hollow beads are laterally spaced from the semiconductor chip and form a frame that completely laterally encloses the semiconductor chip.

After applying the matrix material with the hollow beads embedded therein, the encapsulation element is mechanically bonded to the main surface of the carrier and/or the matrix material with the hollow beads embedded therein using a hot-melt adhesive, for example. In particular, the hollow beads are configured for mechanically stabilizing the intermediate space between the carrier and the encapsulation element in which the semiconductor chip is arranged.

The hollow beads that are at least partially embedded in the matrix material can alternatively or additionally be applied to the main surface of the carrier, to sub-regions of the main surface of the carrier, and/or to the semiconductor chip by means of slot die coating, spray coating or stencil printing.

According to at least one further embodiment of the method, the encapsulation element is structured such that a recess is formed in a main surface of the encapsulation element, wherein the hollow beads are placed in the recess before the encapsulation element is applied to the carrier. In particular, the semiconductor chip is arranged in the recess.

The encapsulation element is structured using a nano-embossing process, for example. For example, the encapsulation element is heated and deformed by pressing in a structured stamp, whereby a recess is formed in the main surface of the encapsulation element. In particular, the hollow beads are at least partially embedded in a matrix material and placed in the recess. This allows the hollow beads to be arranged locally around the semiconductor chip.

Further advantageous embodiments and further developments of the optoelectronic element and of the method for producing an optoelectronic element become apparent from the exemplary embodiments described below in conjunction with the figures.

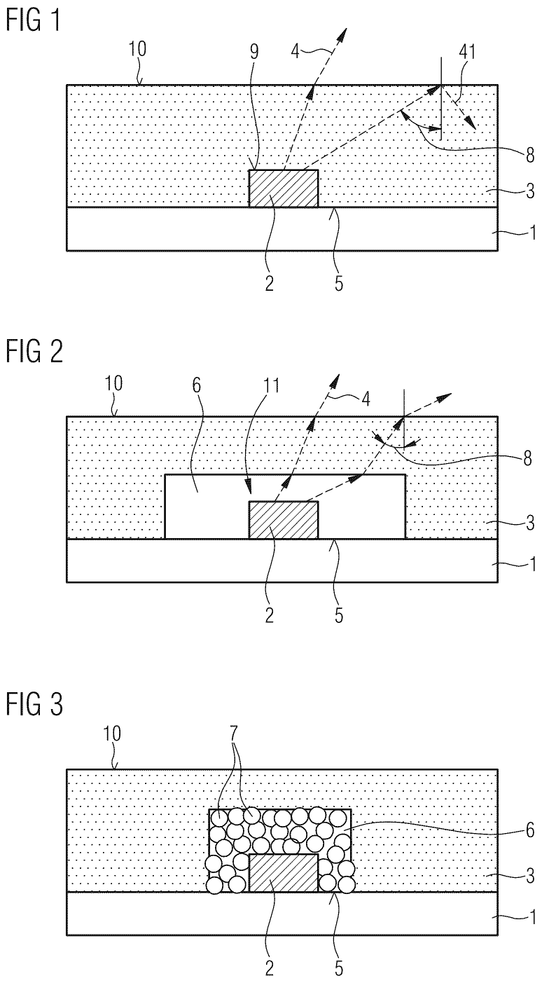

FIGS. 1 and 2 show schematic sectional views of optoelectronic elements according to various examples.

FIGS. 3 to 6 show schematic sectional views of optoelectronic elements according to various exemplary embodiments.

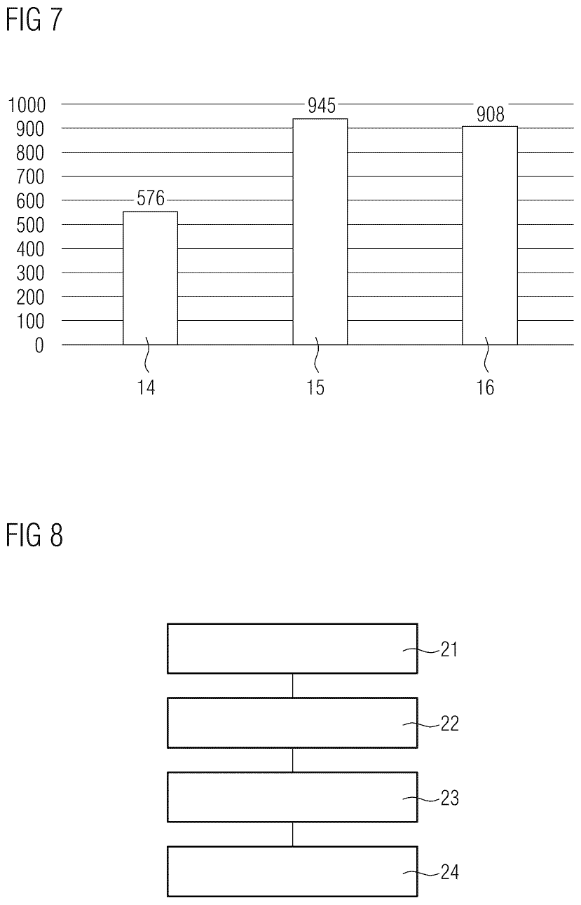

FIG. 7 shows a simulated luminance of optoelectronic elements according to various exemplary embodiments.

FIG. 8 shows a flow diagram with steps of a method for producing an optoelectronic element according to an exemplary embodiment.

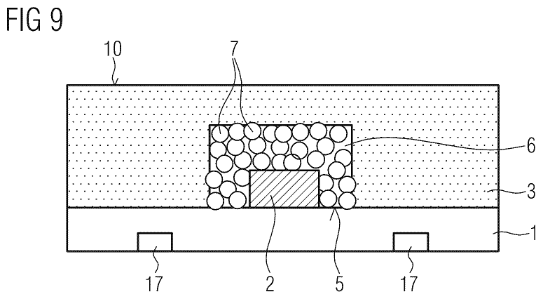

FIG. 9 shows a schematic sectional view of an optoelectronic element according to an exemplary embodiment.

Elements that are identical, similar or have the same effect are marked in the figures with the same reference signs. The figures and the proportions of the elements shown in the figures are not to be regarded as true to scale. Rather, individual elements, in particular layer thicknesses, can be shown exaggeratedly large for better visualization and/or understanding.

The optoelectronic element in FIG. 1 comprises a carrier 1, a semiconductor chip 2 and an encapsulation element 3. The semiconductor chip 2 is arranged on a main surface 5 of the carrier 1 and generates electromagnetic radiation 4 in the visible spectral range during operation. In particular, the semiconductor chip 2 is a flip-chip mini-LED comprising electrical terminal contacts on a side facing the carrier 1. An edge length of the semiconductor chip 2 is at most 100 micrometers, for example. The semiconductor chip 2 is electrically contacted via metallic conductor tracks on the carrier 1. Electromagnetic radiation 4 generated during operation is mostly coupled out of the semiconductor chip 2 via a radiation outcoupling surface 9 of the semiconductor chip 2 facing away from the carrier 1.

The encapsulation element 3 is, for example, a flexible polymer film that is laminated to the main surface 5 of the carrier and to the semiconductor chip 2 arranged thereon. For example, the encapsulation element 3 is mechanically bonded to the main surface 5 of the carrier 1 and to the semiconductor chip 2 using a hot-melt adhesive.

In particular, the optoelectronic element in FIG. 1 comprises no intermediate space between the carrier 1 and the encapsulation element 3 in which the semiconductor chip 2 is arranged. Electromagnetic radiation 4 generated by the semiconductor chip 2 during operation is thus coupled directly into the encapsulation element 3. Electromagnetic radiation 4 generated during operation, which is incident on the radiation outcoupling surface 10 of the encapsulation element 3 at an angle of incidence 8 that is larger than a critical angle of incidence, is in particular totally reflected within the encapsulation element 3.

The radiation outcoupling surface 10 of the encapsulation element 3 corresponds, for example, to a main surface of the encapsulation element 3 facing away from the carrier 1. In particular, the totally reflected electromagnetic radiation 41 is waveguided within the encapsulation element 3, and can emerge at undesired locations, for example at an edge of the optoelectronic element. This reduces the contrast of the optoelectronic element, in particular.

FIG. 2 shows a schematic sectional view of an optoelectronic element which, in contrast to the optoelectronic element in FIG. 1, comprises an intermediate space 6 between the carrier 1 and the encapsulation element 3, in which the semiconductor chip 2 is arranged. The intermediate space 6 forms a closed cavity which is filled, for example, with ambient air or a protective gas and is formed in such a way that a plane-parallel air gap 11 is arranged between the radiation outcoupling surface 9 of the semiconductor chip 2 and the encapsulation element 3. In particular, the plane-parallel air gap 11 is arranged plane-parallel to the main surface 5 of the carrier 1.

Electromagnetic radiation 4 generated by the semiconductor chip 2 during operation is thus not coupled directly into the encapsulation element 3, but is refracted at an interface between the encapsulation element 3 and the intermediate space 6. In particular, this reduces an angle of incidence 8 of the electromagnetic radiation 4 generated during operation at the radiation outcoupling surface 10 of the encapsulation element 3. In particular, this reduces a proportion of totally reflected electromagnetic radiation and improves the emission characteristics of the optoelectronic element.

FIG. 3 shows an exemplary embodiment of an optoelectronic element in which, in comparison to the optoelectronic element in FIG. 2, the intermediate space 6 is filled with hollow beads 7. The hollow beads 7 form a dense sphere packing and consist, in particular, of glass and have an average diameter of between 1 micrometer and 10 micrometers. The average wall thickness of the hollow beads 7 is preferably less than one tenth of the diameter of a hollow bead 7.

The hollow beads 7 are at least partially embedded in a matrix material comprising, for example, silicone, acrylates, polyimides and/or an epoxy resin. The matrix material is configured for mechanically fixing the hollow beads 7. Preferably, the matrix material is used to bond the hollow beads 7 to each other at contact surfaces. In particular, free spaces between the densely packed hollow beads 7 preferably remain largely free of matrix material.

The hollow beads 7, which are at least partially embedded in the matrix material, are designed to mechanically stabilize the intermediate space 6 between the carrier 1 and the encapsulation element 3. The optical properties of the intermediate space 6 filled with hollow beads 7 are similar to the optical properties of the plane-parallel air gap 11 of the optoelectronic element in FIG. 2. In particular, an average refractive index of the intermediate space 6 filled with hollow beads 7 is smaller than a refractive index of the encapsulation element 3.

Thus, the intermediate space 6 filled with hollow beads 7 reduces the portion of totally reflected electromagnetic radiation at the radiation outcoupling surface 10 of the encapsulation element 3 in a similar manner as the plane-parallel air gap. Furthermore, the intermediate space 6 filled with hollow beads 7 is easier and therefore cheaper to manufacture than the plane-parallel air gap 11. In particular, the encapsulation element 3 can be laminated onto the main surface 5 of the carrier 1 and onto the hollow beads 7 using a hot-melt adhesive, for example, with the hollow beads 7 mechanically stabilizing the intermediate space 6.

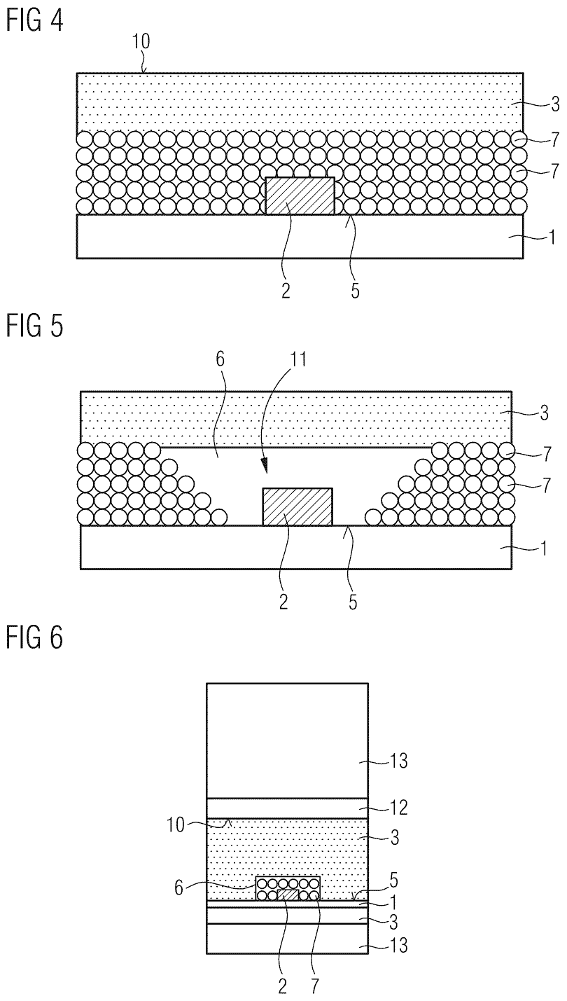

FIG. 4 shows an exemplary embodiment of an optoelectronic element in which, in contrast to FIG. 3, the entire main surface 5 of the carrier 1 and the semiconductor chip 2 are covered with hollow beads 7 which form a dense sphere packing. In particular, the hollow beads 7 form a continuous layer which is arranged between the main surface 5 of the carrier 1 and the encapsulation element 3, and in which the semiconductor chip 2 is embedded. All surfaces of the semiconductor chip 2 that are not covered by the carrier 1 are covered with hollow beads 7. Analogous to the exemplary embodiment in FIG. 3, the hollow beads 7 are configured for reducing the portion of totally reflected electromagnetic radiation at the radiation outcoupling surface 10 of the encapsulation element 3.

FIG. 5 shows an exemplary embodiment of an optoelectronic element in which the hollow beads 7 are arranged laterally spaced from the semiconductor chip 2 compared to the exemplary embodiment in FIG. 4. In particular, the hollow beads 7 form a frame that completely surrounds the semiconductor chip 2 and protrudes in a direction perpendicular to the main surface 5 of the carrier 1, such that a plane-parallel air gap 11 is arranged between the semiconductor chip 2 and the encapsulation element 3, analogous to FIG. 2. The dense sphere packing of hollow beads 7 preferably comprises a reflective surface, so that electromagnetic radiation emitted laterally by the semiconductor chip 2 is deflected in the direction of the encapsulation element 3.

FIG. 6 shows a schematic sectional view of an optoelectronic element which, compared to the exemplary embodiment in FIG. 3, additionally comprises a diffuser 12 and a cover glass 13, wherein the diffuser 12 is arranged on the radiation outcoupling surface 10 of the encapsulation element 3 and the cover glass 13 is applied to a main surface of the diffuser 12 facing away from the encapsulation element 3. Furthermore, the optoelectronic element comprises a further encapsulation element 3 and a further cover glass 13 on a main surface of the carrier 1 opposite to the semiconductor chip 2.

The diffuser 12 comprises, for example, a silicone with a low refractive index in which scattering particles are embedded. The scattering particles comprise, for example, aluminum oxide. During operation, a large portion, for example more than 90%, of the electromagnetic radiation generated by the semiconductor chip 2 is emitted in a direction away from the carrier 1.

FIG. 7 shows results of a numerical simulation of a luminance of different optoelectronic elements. In particular, the simulated luminance 14, 15, 16 of the electromagnetic radiation 4 emitted by the semiconductor chip 2 in the forward direction, i.e. in a direction perpendicular to the main surface 5 of the carrier 1, is shown. The luminance 14, 15, 16 is given in nits. The structure of the simulated optoelectronic elements essentially corresponds to the exemplary embodiment shown in FIG. 6 and differs only in the presence or absence of the intermediate space 6, which is filled either with air or with hollow beads 7. In particular, the carrier 1 is a PET film and the encapsulation element 3 is a PVB film with a thickness of approximately 1.5 millimeters. The diffuser 12 has a thickness of approximately 300 micrometers and comprises scattering particles of aluminum oxide with a weight fraction of approximately 3%. The cover glass 13 comprises a thickness of approximately 2 millimeters. Thickness specifications here refer to a direction perpendicular to the main surface 5 of the carrier 1.

The first luminance 14 corresponds to a simulated optoelectronic element comprising no intermediate space 6 between the carrier and the encapsulation element 3. In particular, the encapsulation element 3 is applied directly to the semiconductor chip 2. The simulated luminance 14 of the optoelectronic element in the forward direction corresponds to 576 nits.

The second luminance 15 corresponds to a simulated optoelectronic element comprising an air-filled intermediate space 6 between the carrier 1 and the encapsulation element 3. The intermediate space 6 has a linear lateral extent of approximately 500 micrometers and a height of approximately 120 micrometers, with the semiconductor chip 2 comprising an edge length of approximately 100 micrometers. The height specification here refers to a direction perpendicular to the main surface 5 of the carrier 1. Here, in particular, a plane-parallel air gap 11 is arranged between the semiconductor chip 2 and the encapsulation element 3. In this case, the simulated luminance 15 of the optoelectronic element is 945 nits. The plane-parallel air gap 11 thus increases the luminance of the electromagnetic radiation coupled out in the forward direction by a factor of approximately 1.64.

The third luminance 16 corresponds to a simulated optoelectronic element, whereby, in contrast to the second simulated luminance 15, the intermediate space 6 is filled with hollow beads 7. Here, the dimensions of the intermediate space 6 are the same. In particular, the hollow beads 7 are made of glass and have a diameter of approximately 10 micrometers with a wall thickness of approximately one micrometer. The hollow beads 7 form a dense sphere packing. In this case, the simulated luminance 16 of the optoelectronic element is 908 nits. The intermediate space 6 filled with hollow beads 7 thus leads to a similar increase in the luminance 16 emitted in the forward direction as the plane-parallel air gap 11.

The flow diagram in FIG. 8 schematically shows a sequence of a method according to an exemplary embodiment. In the first step 21, a carrier 1 is provided. In particular, the carrier 1 is a flexible film and comprises metallic conductor tracks for contacting a semiconductor chip 2 to be applied thereto.

In the second step 22, a semiconductor chip 2 is applied to a main surface 5 of the carrier 1. The semiconductor chip 2 is electrically contacted with the metallic conductor tracks on the carrier 1. The semiconductor chip 2 is, in particular, a light-emitting diode, preferably a mini-LED or a micro-LED with an edge length of at most 100 micrometers, and generates electromagnetic radiation 4 in the visible spectral range during operation.

In the third step 23, hollow beads 7, which are at least partially embedded in a matrix material, are applied to at least a sub-region of the main surface 5 of the carrier 1. The hollow beads 7 are preferably made of glass and are transparent to electromagnetic radiation 4 generated by the semiconductor chip 2 during operation. The hollow beads 7 have, for example, an average diameter of 10 micrometers. The matrix material is, for example, an epoxy resin and bonds the hollow beads 7 together only at certain points. The matrix material with the hollow beads 7 at least partially embedded therein is applied, for example, to at least a sub-region of the main surface 5 of the carrier 1 by means of a slot die coating. Alternatively and/or additionally, the matrix material with the hollow beads 7 at least partially embedded therein can also be applied by spray coating, stencil printing or screen printing. The matrix material with the hollow beads 7 at least partially embedded therein completely covers areas of the semiconductor chip 2 that are not covered by the carrier 1. Alternatively, the matrix material with the hollow beads 7 at least partially embedded therein can be arranged at a lateral distance from the semiconductor chip 2 and form a frame that completely surrounds the semiconductor chip 2.

In the fourth step 24, an encapsulation element 3 is arranged on the main surface 5 of the carrier 1. The encapsulation element 3 is, in particular, a flexible film and is laminated onto the main surface 5 of the carrier 1 using a hot-melt adhesive, for example. The encapsulation element 3 completely covers the hollow beads 7 and the semiconductor chip 2, such that an intermediate space 6 is created between the carrier 1 and the encapsulation element 3. The hollow beads 7 and the semiconductor chip 2 are arranged in the intermediate space 6.

FIG. 9 shows an exemplary embodiment of an optoelectronic element. Compared to the optoelectronic element described in connection with FIG. 3, the optoelectronic element in FIG. 9 additionally comprises terminal contacts 17, which are arranged on a side of the carrier 1 opposite the main surface 5. The terminal contacts 17 are arranged for external electrical contact with the optoelectronic element. Furthermore, the terminal contacts 17 are arranged for mounting the optoelectronic element on an external surface. The optoelectronic element can thus be surface-mounted.

This patent application claims the priority of the German patent application DE 102021132495.5, the disclosure content of which is hereby incorporated by reference.

The invention is not limited to the exemplary embodiments by the description thereof. Rather, the invention includes any new feature as well as any combination of features, which includes, in particular, any combination of features in the patent claims, even if this feature or combination itself is not explicitly stated in the patent claims or exemplary embodiments.

### LIST OF REFERENCE SIGNS

1 carrier
2 semiconductor chip
3 encapsulation element
4 electromagnetic radiation
41 totally reflected electromagnetic radiation
5 main surface of the carrier
6 intermediate space
7 hollow beads
8 angle of incidence
9 radiation outcoupling surface of the semiconductor chip
10 radiation outcoupling surface of the encapsulation element
11 plane-parallel air gap
12 diffuser
13 cover glass
14 first luminance
15 second luminance
16 third luminance
17 terminal contact
21 first step
22 second step
23 third step
24 fourth step

The invention claimed is:

1. An optoelectronic element comprising:
a carrier,
a semiconductor chip with an active layer for generating electromagnetic radiation, and
an encapsulation element, wherein
the semiconductor chip is arranged on a main surface of the carrier,
the encapsulation element is arranged exclusively on the main surface of the carrier, such that the optoelectronic element comprises an intermediate space between the main surface of the carrier and the encapsulation element,
the semiconductor chip is arranged in the intermediate space, and
the intermediate space is at least partially filled with hollow beads.

2. The optoelectronic element according to claim 1, wherein
the carrier and/or the encapsulation element comprises a flexible film.

3. The optoelectronic element according to claim 1, wherein
the carrier and the encapsulation element are transparent to electromagnetic radiation generated by the semiconductor chip during operation.

4. The optoelectronic element according to claim 1, wherein
the semiconductor chip has an edge length of at most 500 micrometers.

5. The optoelectronic element according to claim 1, wherein
the hollow beads are made of glass.

6. The optoelectronic element according to claim 1, wherein
the hollow beads have an average diameter between 1 micrometer and 100 micrometers, inclusive.

7. The optoelectronic element according to claim 1, wherein
the hollow beads are transparent to electromagnetic radiation generated by the semiconductor chip during operation.

8. The optoelectronic element according to claim 1, wherein
the hollow beads form a dense sphere packing, wherein the dense sphere packing completely fills the intermediate space.

9. The optoelectronic element according to claim 1, wherein
the intermediate space extends over the entire main surface of the carrier.

10. The optoelectronic element according to claim 1, wherein
the intermediate space is a closed cavity.

11. The optoelectronic element according to claim 1, wherein
the hollow beads are at least partially embedded in a matrix material, and
the matrix material connects the hollow beads in a mechanically stable manner.

12. The optoelectronic element according to claim 11, wherein
the matrix material does not completely fill spaces between the hollow beads.

13. The optoelectronic element according to claim 1, wherein
the hollow beads are arranged laterally spaced from the semiconductor chip, and
the hollow beads comprise a reflective surface.

14. A method for producing an optoelectronic element comprising the steps of:
providing a carrier,
applying a semiconductor chip onto a main surface of the carrier, wherein the semiconductor chip comprises an active layer for generating electromagnetic radiation, and
applying an encapsulation element exclusively onto the main surface of the carrier, wherein
an intermediate space is formed between the encapsulation element and the main surface of the carrier,
the semiconductor chip is arranged in the intermediate space, and
the intermediate space is at least partially filled with hollow beads.

15. The method according to claim 14, wherein
the hollow beads are at least partially embedded in a matrix material and are applied onto the main surface of the carrier by a screen printing process before the encapsulation element is applied.

16. The method according to claim 14, wherein
the encapsulation element is structured such that a recess is formed in a main surface of the encapsulation element, and
hollow beads are placed in the recess before the encapsulation element is applied to the carrier, wherein
the semiconductor chip is arranged in the recess.
